(19) United States
(12) Patent Application Publication
(10) Pub. No.: US 2026/0182466 A1
(43) Pub. Date: Jun. 25, 2026

(54) THREE-DIMENSIONAL HETEROGENEOUS INTEGRATION MEMORY STACKS WITH REDUCED HYBRID BOND PAD, THROUGH-SILICON VIA, AND PACKAGE-LEVEL BOND PAD PITCHES

(71) Applicant: Micron Technology, Inc., Boise, ID (US)

(72) Inventors: Bharat Bhushan, Boise, ID (US); Kunal R. Parekh, Boise, ID (US); Akshay N. Singh, Boise, ID (US)

(21) Appl. No.: 19/411,146

(22) Filed: Dec. 5, 2025

Related U.S. Application Data
(60) Provisional application No. 63/737,493, filed on Dec. 20, 2024.

(51) Int. Cl. H10W 90/20; H10B 80/00; H10D 80/30; H10P 74/00; H10W 20/20; H10W 72/90; H10W 74/01; H10W 74/10; H10W 90/00

(52) U.S. Cl. CPC H10W 90/291; H10W 20/2134; H10W 72/963; H10W 72/967; H10W 74/121; H10W 90/297; H10W 90/792; H10B 80/00; H10D 80/30; H10P 74/273; H10W 74/01

(57) ABSTRACT

Three-dimensional heterogeneous integration memory stacks with reduced hybrid bond pad, through-silicon via, and package-level bond pad pitches (and associated systems and methods) are disclosed herein. In one embodiment, a memory stack includes an interface (IF) logic die and a plurality of memory cubes arranged in a vertical stack on the IF logic die. Each memory cube of the plurality of memory cubes includes a plurality of memory dies. The memory stack can further include gapfill material disposed over the IF logic die and laterally adjacent each of the memory cubes. The gapfill material can be further disposed over a topmost die of each memory cube, forming a continuous structure. The memory dies can include through-silicon vias and hybrid bond pads arranged with a pitch of less than or equal to 3 micrometers. The memory stack can be incorporated into a memory system with a logic die on a system substrate.

### CROSS-REFERENCE TO RELATED APPLICATION(S)

The present application claims priority to U.S. Provisional Patent Application No. 63/737,493, filed Dec. 20, 2024, the disclosure of which is incorporated herein by reference in its entirety.

### TECHNICAL FIELD

This disclosure relates generally to memory devices. For example, several embodiments of the present technology relate to three-dimensional heterogeneous integration (3DHI) memory stacks with reduced hybrid bond pad pitches, reduced through-silicon via (TSV) pitches, and/or reduced package-level bond pad pitches.

### BACKGROUND

Memory devices have become increasingly important components in modern computing systems, enabling storage and rapid access to large amounts of data. As technology advances, there is a growing demand for memory devices with higher capacity, faster performance, and improved energy efficiency. To meet these demands, the semiconductor industry has been exploring various approaches to increase memory density and enhance overall system performance.

One approach that has gained significant attention is three-dimensional (3D) stacking of memory devices. This technique involves stacking multiple layers of memory dies (or chips) vertically, allowing for a higher density of storage elements within a given footprint. 3D stacking offers the potential to dramatically increase memory capacity while maintaining or even reducing the overall chip size.

Another area of focus in memory device development is heterogeneous integration, which involves combining different types of components or technologies within a single package. This approach can enable the integration of memory with logic circuits, sensors, or other functional elements, potentially leading to improved system performance and reduced power consumption.

As memory devices become more complex and densely integrated, challenges arise in terms of interconnection and packaging. The ability to create reliable electrical connections between stacked dies and to the external package becomes increasingly critical. Traditional packaging and interconnect technologies may struggle to keep pace with the demands of advanced memory architectures.

Furthermore, as the dimensions of memory devices continue to shrink, the pitch of various components, such as bond pads and through-silicon vias (TSVs), becomes a limiting factor in achieving higher integration densities. Reducing the pitch of these elements while maintaining electrical performance and manufacturability presents significant technical challenges.

Energy efficiency is another important consideration in the development of advanced memory devices. As data centers and mobile devices consume ever-increasing amounts of data, there is a growing need for memory solutions that can deliver high performance while minimizing power consumption.

The semiconductor industry continues to explore innovative solutions to address these challenges and push the boundaries of memory technology. Advancements in materials science, fabrication processes, and design techniques are all contributing to the ongoing evolution of memory devices.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates a cross-sectional view of a memory system configured in accordance with various embodiments of the present technology.

FIG. 2 is a flow diagram illustrating a method of manufacturing a memory device or memory system in accordance with various embodiments of the present technology.

FIGS. 3A-3D illustrate cross-sectional views of a memory device/memory system at various stages of manufacturing, in accordance with various embodiments of the present technology.

FIG. 4 is a schematic showing a system that includes a semiconductor device assembly configured in accordance with various embodiments of the present technology.

### DETAILED DESCRIPTION

The present technology relates to three-dimensional heterogeneous integration (3DHI) memory stacks with reduced pitch for various components, and to (a) systems incorporating such memory stacks and (b) methods of manufacturing the same. These memory stacks comprise multiple memory dies (e.g., 24 DRAM dies) stacked on an interface logic die, featuring through-substrate vias (TSVs) and bond pads with a pitch of less than 3 μm. One or more memory stacks and one or more logic dies can be directly stacked on a system substrate, which is expected to obviate the use of separate interposers, package substrates, and printed circuit boards. Such integration with a system substrate can be facilitated by interconnects formed in a metallization layer dielectric positioned between (a) the memory stack(s) and/or the logic die(s) and (b) the system substrate.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

Many memory devices utilize three-dimensional (3D) stacking of memory dies to increase storage density within a given footprint. This approach allows for higher memory capacity while maintaining or reducing overall chip size. However, as memory devices become more complex and densely integrated, challenges arise in creating reliable electrical connections between stacked dies and to external packages. Traditional packaging and interconnect technologies often struggle to keep pace with the demands of advanced memory architectures.

A key limitation in achieving higher integration densities is the pitch of various components, such as bond pads and through-silicon vias (TSVs). Many existing memory devices have relatively large pitches for these elements, which constrains the overall density and performance of the memory system. For example, many high-bandwidth memory (HBM) devices typically have a 100 μm pitch for package-level bond pads. This large pitch limits the number of connections that can be made in a given area, potentially restricting bandwidth and increasing power consumption.

Furthermore, many current memory systems rely on separate interposers, package substrates, and printed circuit boards (PCBs) to integrate memory stacks with logic components. This multi-layer approach can introduce additional complexity, increase manufacturing costs, and potentially impact system performance due to longer interconnect distances. As the demand for higher performance and lower energy consumption in memory systems continues to grow, these limitations present significant challenges for further advancement in memory technology.

The present technology addresses the challenges associated with three-dimensional (3D) stacking of memory dies and heterogeneous integration by providing innovative solutions for reducing the pitch of critical components and simplifying system architecture. Several embodiments of the disclosed technology are directed to memory systems comprising one or more memory stacks and one or more logic dies stacked on system substrates. The memory stack(s) can each include a plurality of memory dies (e.g., 24 DRAM dies) stacked on an interface logic die, with through-substrate vias (TSVs) and bond pads having a pitch of less than 3 μm (e.g., less than 1 μm). This significant reduction in pitch compared to other designs is expected to enable higher integration density and improved performance.

Furthermore, the disclosed technology obviates the use of separate interposers, package substrates, and printed circuit boards (PCBs) by integrating the memory stack(s) and logic die(s) directly on a system substrate (e.g., using back-end-of-line metal layers, metallization layer dielectric structures, redistribution layers, etc.). This approach simplifies the overall system architecture, reduces manufacturing complexity and cost, and potentially improves system performance by shortening interconnect distances. In several embodiments, the memory stack and logic die can be coupled to each other and to TSVs in the system substrate via interconnects formed in a metallization layer dielectric, facilitating efficient communication and power distribution.

The present technology is expected to offer several advantages over other memory devices and systems. For example, the reduced pitch of bond pads, TSVs, and package-level bond pads (e.g., ≤10 μm pitch for memory stack-to-substrate connection points) allows for increased parallelism, potentially leading to lower resistance and reduced energy usage (e.g., <0.1 pJ/bit). As another example, the direct stacking of memory and logic components on the system substrate is expected to obviate the use of intermediate substrates, potentially reducing manufacturing costs and improving thermal performance. Additionally, the present technology is expected to enable larger memory die stacks (e.g., 24-high die stacks or larger) in a single package, thereby enabling higher memory capacities within a given footprint, addressing the growing demand for increased storage density in modern computing systems.

### B. Selected Embodiments of Three-Dimensional Heterogeneous Integration Memory Stacks with Reduced Pitches, and Associated Systems, Devices, and Methods

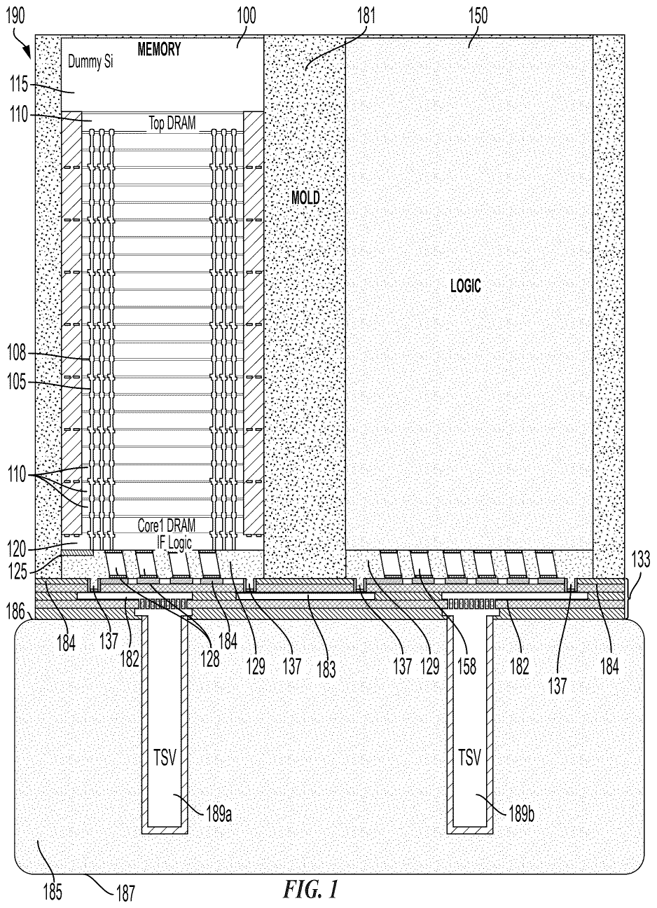

FIG. 1 illustrates a cross-sectional view of a memory system 190 configured in accordance with various embodiments of the present technology. As shown, the memory system 190 includes a system substrate 185 having a first side 186 (e.g., a frontside) and a second side 187 (e.g., a backside) opposite the first side 186. The memory system 190 further includes a memory stack 100 and a logic die 150 stacked on the first side 186 of the system substrate 185.

The memory stack 100 includes a plurality of memory dies 110 stacked on an interface logic die 120. The memory stack 100 may therefore also be referred to herein as 3D stacked memory, a 3D stack, and the like. In the illustrated embodiment, the memory stack 100 includes 24 memory dies 110, which can include dynamic random-access memory (DRAM) dies and/or another suitable type of memory dies. In other embodiments, the memory stack 100 can include a different number of memory dies 110 (e.g., fewer than 24 memory dies or greater than 24 memory dies). The memory stack 100 further includes through substrate vias (TSVs) 105 and bond pads 108. The TSVs 105 and bond pads 108 can be formed of copper or another suitable conductive material, such as tungsten. In some cases, the TSVs 105 and bond pads 108 can be disposed with a pitch of less than 3 μm (e.g., less than 1 μm).

The memory stack 100 can further include a dummy silicon substrate 115 stacked on top of the uppermost memory die 110. In other embodiments, the dummy silicon substrate 115 can be omitted. At the bottom of the interface logic die 120, the memory stack 100 includes package-level bond pads 128. The package-level bond pads 128 can be formed of copper or another suitable conductive material, and can be disposed with a pitch of less than or equal to 10 μm. In some embodiments, the memory stack 100 includes pads 125 formed at the bottom of the interface logic die 120. The pads 125 can be formed of aluminum or another suitable conductive material. In these and other embodiments, the pads 125 can be used for testing or probing the memory stack 100, such as to verify that the memory stack 100 is functioning properly.

The memory stack 100 can be stacked on top of and bonded to a metallization layer dielectric 133. The metallization layer dielectric 133 can be formed as part of forming back-end-of-line (BEOL) metal layers and/or a redistribution layer (RDL). In some cases, the bonding between the memory stack 100 can the metallization layer dielectric 133 can be performed using stack-on-substrate (SoS) and/or front-to-front (F2F) thermo-compression bonding (TCB). An underfill material 129 can be used to fill in gaps between the memory stack 100 and the metallization layer dielectric 133. The underfill material 129 can protect and isolate conductive connections between the package-level bond pads 128 and a plating layer 184.

The plating layer 184 can extend across all or a subset of a top surface of the metallization layer dielectric 133. Additionally, or alternatively, the plating layer 124 can line sidewalls and bottoms of recesses 137 formed in the metallization layer dielectric 133. The plating layer 184 can be coupled to interconnects 182 (e.g., metal layers, traces, vias) formed in the metallization layer dielectric 133. These interconnects 182 can, in turn, be coupled to interconnects and/or through substrate vias 189a or 189b formed in the system substrate 185. In some embodiments, the plating layer 184 can be used for testing the memory system 190, such as for supplying power to the system 190 to test connections between the memory stack 100 and the logic die 150 (e.g., via one or more interconnects 183 formed in the metallization layer dielectric 133). In these and other embodiments, the plating layer 184 can facilitate connections with external systems and/or components.

The logic die 150 can be stacked on top of the metallization layer dielectric 133, such as using an SoS and/or F2F TCB, similar to the memory stack 100. The logic die 150 can include package-level bond pads 158 that can be coupled to the plating layer 184. The logic die 150 can be a host device, a graphics processing unit (GPU), a tensor computing unit (TCU), a central processing unit (CPU), an artificial intelligence (AI) accelerator, or the like. As discussed above, the logic die 150 can be coupled to the memory stack 100 via the one or more interconnects 183 formed in the metallization layer dielectric 133. These interconnects 183 can include metal layers, traces, and/or vias.

The system substrate 185 can include one or more TSVs and/or other interconnect structures. For example, the system substrate 185 shown in FIG. 1 includes through substrate vias 189a and 189b, which can be giant TSVs in some embodiments. The through substrate vias 189a and 189b can be coupled to the memory stack 100 and the logic die 150, respectively, via the interconnects 182 in the metallization layer dielectric 133, the plating layer 184, and/or respective package-level bond pads 128, 158.

An encapsulant 181, which can be a mold compound, can be used to encapsulate the memory stack 100 and the logic die 150 above the first side 186 of the system substrate 185. This encapsulation can provide protection and structural support for the components of the memory system 190.

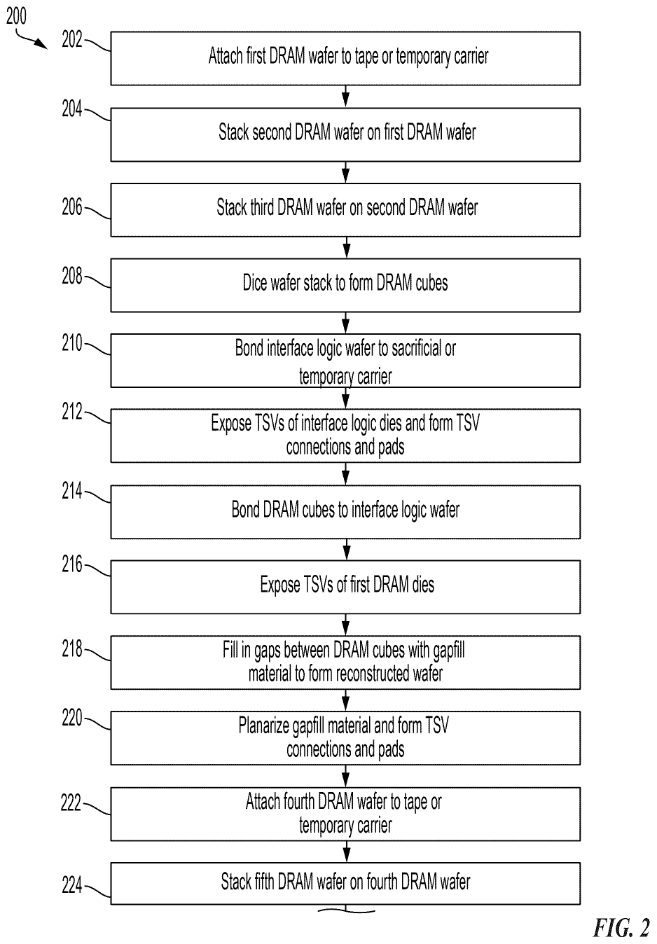

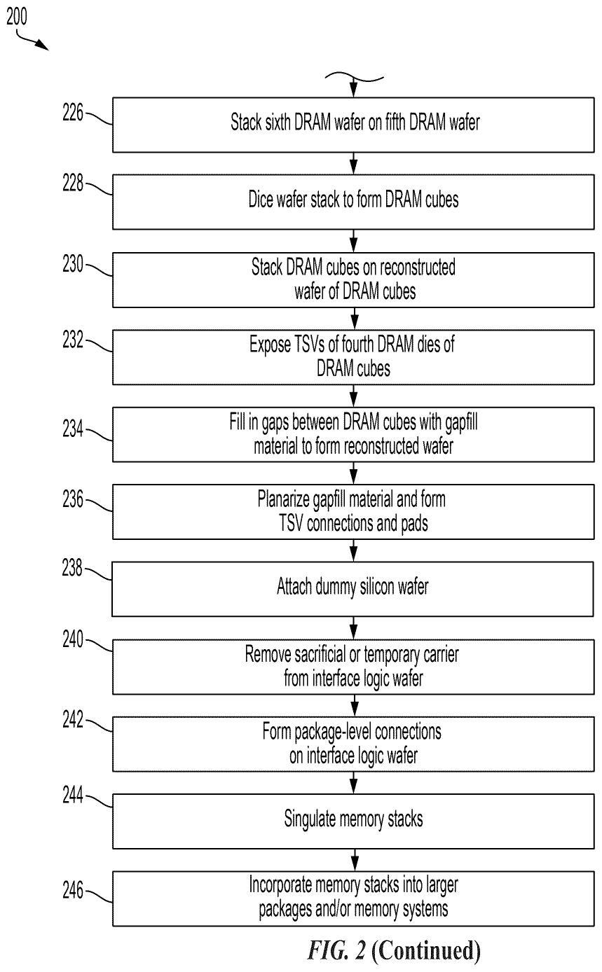

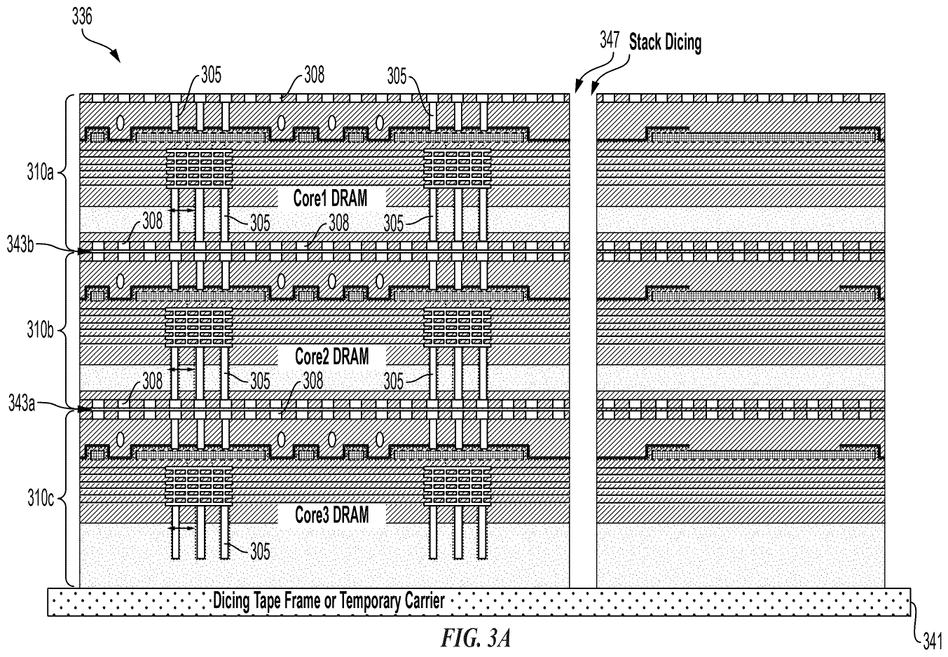

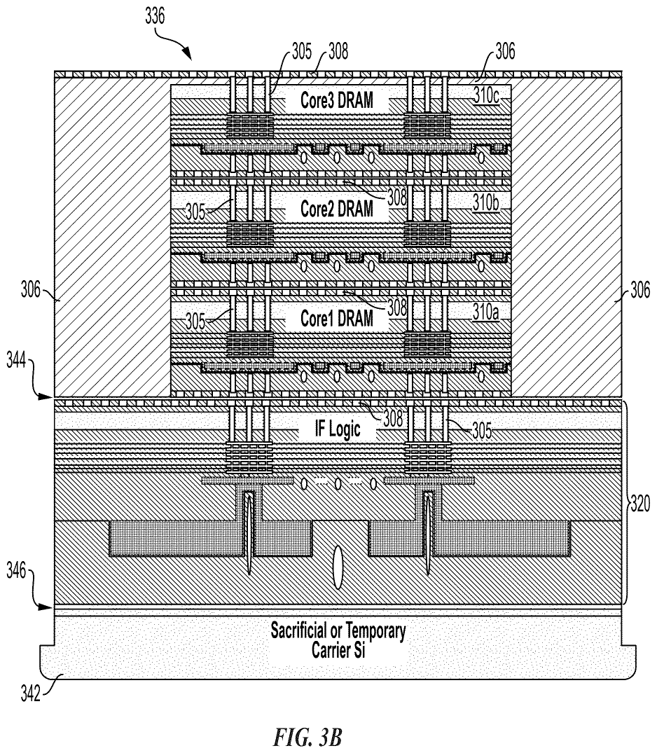

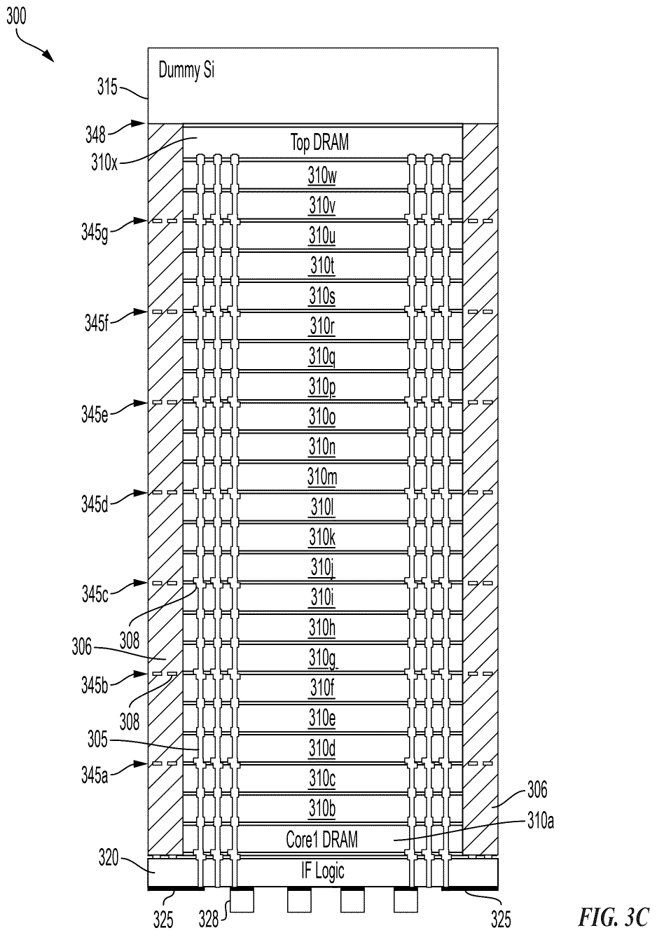

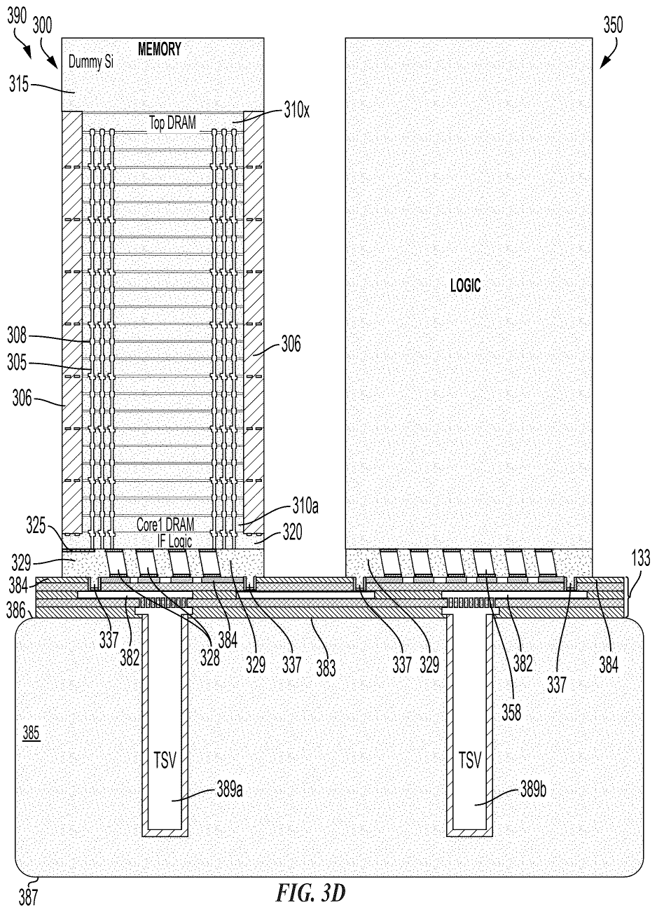

FIG. 2 illustrates a method 200 of manufacturing in accordance with various embodiments of the present technology. For example, the method 200 can be a method for manufacturing (i) a memory stack (e.g., the memory stack 100 of FIG. 1) with reduced hybrid bond and TSV pitch for three-dimensional heterogeneous integration systems and devices and/or (ii) a memory system (e.g., the memory system 190 of FIG. 1). The method 200 is illustrated as a series of blocks 202-246 or steps. Several of the blocks 202-246 are described in detail below as stacking DRAM wafers for the sake of example. Indeed, the present technology is not limited to DRAM wafers, and the principles disclosed herein can be extended and applied to stacking wafers of other types of memory dies. In addition, all or a subset of any one or more of the blocks 202-246 of the method 200 can be executed in accordance with the discussion above (e.g., with reference to FIG. 1) and/or with the discussion below. Indeed, several of the blocks 202-246 of the method 200 are discussed in detail below with reference to FIGS. 3A-3D that illustrate cross-sectional views of a memory device/memory system at various stages of manufacturing, in accordance with various embodiments of the present technology.

The method 200 begins at block 202 by attaching a first DRAM wafer to a tape or temporary carrier. Referring to FIGS. 2 and 3A together for the sake of example, a backside of a first DRAM wafer 310c can be attached to a tape (e.g., a dicing tape frame) or a temporary carrier 341 using a removable adhesive. The first DRAM wafer 310c can be an unthinned wafer in some embodiments, as is shown in FIG. 3A with TSVs 305 covered by excess silicon at the backside of the first DRAM wafer 310c. In these and other embodiments, the first DRAM wafer 310c can be a wafer of known good die (e.g., DRAM die subjected to probing/testing and verified as properly functional before use at block 202 of the method 200).

At block 204, the method 200 continues by stacking a second DRAM wafer on the first DRAM wafer. Referring again to FIGS. 2 and 3A together for the sake of example, a second DRAM wafer 310b (e.g., a thinned DRAM wafer) can be stacked onto the frontside of the first wafer 310c such that a backside of the second wafer 310b is bonded to a frontside of the first wafer 310c using a first wafer-to-wafer (W2W) front-to-back (F2B) hybrid bond (HB) 343a. In some embodiments, the second DRAM wafer 310b can be bonded to a sacrificial wafer (not shown) using a W2W F2B fusion bond (FB), such as before being stacked on the first DRAM wafer 310c. Such an arrangement can allow (a) forming TSV connections and bond pads 308 at a backside of the second DRAM wafer 310b, (b) stacking of the second DRAM wafer 310b onto the first wafer 310c, and/or (c) subsequent thinning of the second DRAM wafer 310b to expose TSVs 305 and form TSV connections and hybrid bond pads 308 at a frontside of the second DRAM wafer 310b. In some cases, a pitch of the TSVs 305 and hybrid bond pads 308 can be less than 3 μm (e.g., less than 1 μm). The second wafer 310 b can be a wafer of known good die (e.g., DRAM die subjected to probing/testing and verified as properly functional before use at block 204 of the method 200).

At block 206, the method 200 continues by stacking a third DRAM wafer on the second DRAM wafer. Referring again to FIGS. 2 and 3A for the sake of example, a third DRAM wafer 310a (e.g., a thinned DRAM wafer) can be stacked onto the frontside of the second wafer 310b such that a backside of the third wafer 310a is bonded to a frontside of the second wafer 310b using a second W2W F2B hybrid bond 343b. In some embodiments, the third DRAM wafer can be bonded to a sacrificial wafer (not shown) using a W2W F2B fusion bond, such as before being stacked on the second DRAM wafer 310b and/or before the second DRAM wafer 310b is stacked on the first DRAM wafer 310c. Such an arrangement can allow (a) forming TSV connections and hybrid bond pads 308 at a backside of the third DRAM wafer 310a and/or at the backside of the second DRAM wafer 310b, (b) stacking of the third DRAM wafer 310a onto the second wafer 310b, (c) stacking of the second wafer 310b onto the third wafer 310a, and/or (c) subsequent thinning of the third DRAM wafer 310a and/or the second DRAM wafer 310b to expose TSVs 305 and form TSV connections and hybrid bond pads 308 at a frontside of the third DRAM wafer 310a and/or the frontside of the second DRAM wafer 310b, respectively. In some cases, a pitch of the TSVs 305 and hybrid bond pads 308 can be less than 3 μm (e.g., less than 1 μm). The third wafer 310a can be a wafer of known good die (e.g., DRAM die subjected to probing/testing and verified as properly functional before use at block 206 of the method 200).

At block 208, the method 200 continues by dicing the wafer stack to form singulated DRAM cubes. A singulated DRAM cube 336 is shown in FIG. 3A beside a dicing street 347 for the sake of example. More specifically, referring to FIGS. 2 and 3A together, the wafer stack resulting from the stack of first through third DRAM wafers 310a-310c can be diced to realize a plurality of three-dimensional stacks (3DS) of memory dies (referred to herein as DRAM cubes 336) that are each three-die high. The present technology is not limited to stacking three wafers together before dicing to realize a plurality of DRAM cubes 336. Indeed, a different number of wafers (e.g., two or more than three DRAM wafers) can be stacked together before dicing in other embodiments of the present technology. That said, there can be a yield concern with stacking a large number of DRAM wafers together before dicing to realize a plurality of DRAM cubes 336. For example, if any given wafer includes 1,000 DRAM dies and 12 of the DRAM dies in the wafer are bad (e.g., faulty, malfunctioning) at seemingly random locations, then stacking multiple such wafers together can increase the number of singulated DRAM cubes 336 that will include at least one faulty DRAM die. As such, limiting the wafer stack height before dicing into a plurality of DRAM cubes 336 can facilitate testing, identifying, and disposing of malfunctioning DRAM cubes 336 with a smaller number of dies. In other words, limiting the wafer stack height before dicing into a plurality of DRAM cubes 336 can facilitate wasting less material than disposing of malfunctioning DRAM cubes that have a larger number of memory dies.

At block 210, the method 200 continues by bonding an interface logic wafer to a sacrificial or temporary carrier. Referring to FIGS. 2 and 3B together for the sake of example, an interface (IF) logic wafer 320 can be attached to a sacrificial or temporary carrier 342 using a wafer-to-wafer (W2W) front-to-front (F2F) fusion bond 346. In some embodiments, the IF logic wafer 320 can be a reconstructed/reconstituted wafer formed by bonding a plurality of IF logic die (e.g., known good IF logic die) to the sacrificial or temporary carrier 342, such as using chip-to-wafer reconstruction (C2WR) front-to-front (F2F) fusion bonds 346. In some cases, gaps between interface logic die used to reconstruct the IF wafer 320 can be filled with gapfill material, such as silicon oxide, silicon monoxide, or another suitable gapfill material. The interface logic dies can be memory controllers, interface dies, or the like.

With continuing reference to FIGS. 2 and 3B together, the method 200, at block 212, continues by exposing TSVs 305 of interface logic dies in the interface logic wafer 320 and forming TSV connections and hybrid bond pads 308 (also referred to herein as backside pads) at a backside of the interface logic wafer 320. In some cases, a dielectric (e.g., oxide) layer can be created on the backside of the IF logic wafer 320 with a plurality of hybrid bond pads 380 disposed within the dielectric layer, and the dielectric layer can be planarized (e.g., using chemical mechanical polishing (CMP)). As shown in FIG. 3B, the hybrid bond pads 308 can outnumber the TSVs 305 and can be distributed across the IF logic wafer 320 (including at locations that will ultimately be positioned beneath gapfill material 306). Such a distribution of hybrid bond pads 308 is expected to help maintain uniformity of chemical mechanical polishing. In some cases, a pitch of the hybrid bond pads 308 can be less than 3 μm (e.g., less than 1 μm). Hybrid bond pads 308 not coupled to a TSV 305 and/or positioned beneath gapfill material 306 can be dummy pads.

At block 214, the method 200 continues by bonding DRAM cubes to the interface logic wafer. Referring to FIGS. 2 and 3B together, singulated DRAM cubes 336 can be inverted such that frontsides of third DRAM dies 310a of the DRAM cubes 336 are placed face down on a backside of the IF logic wafer 320. The inverted DRAM cubes 336 can be stacked on the backside of the IF logic wafer 320 such that frontsides of the third DRAM dies 310a of the DRAM cubes 336 can be bonded to the backside of the IF logic wafer 320 using stack-to-wafer-reconstruction (S2WR), front-to-back (F2B) hybrid bonds 344. In some embodiments, the inverted DRAM cubes 336 can be known good stacks (KGS) as confirmed via functionality testing (e.g., verified through probing/testing) prior to stacking on and bonding to the IF logic wafer 320.

With continuing reference to FIGS. 2 and 3B together, the method 200, at block 216, continues by exposing TSVs 305 of first DRAM dies 310c of the DRAM cubes 336. In some cases, the first DRAM dies 310c of the DRAM cubes 336 can be thinned (e.g., after removal of the tape/temporary carrier 341 of FIG. 3A) to expose TSVs 305. The thinning can be performed after stacking the DRAM cubes 336 on the interface logic wafer 320 but before filling gaps with gapfill material 306 per block 218 of the method 200 below. Alternatively, the thinning can be performed before stacking the DRAM cubes 336 on the IF logic die 320, such as before filling gaps with gapfill material 306 per block 218 below. Alternatively, the thinning can be performed after stacking the DRAM cubes 336 on the IF logic die 320, such as after filling gaps with gapfill material 306 per block 218 below.

At block 218, the method 200 continues by filling in gaps between the DRAM cubes 336 with gapfill material 306 to form a reconstructed wafer. Any suitable gapfill material 306 can be used, such as silicon oxide or silicon monoxide. The gapfill material 306 can fill gaps between the DRAM cubes 336. Additionally, or alternatively, the gap fill material 306 can be disposed over backsides of the first DRAM dies 310c (corresponding to tops of the DRAM cubes 336). In some embodiments, portions of the gapfill material 306 disposed laterally adjacent the DRAM cubes 336 (e.g., within gaps between adjacent DRAM cubes 336) and portions of the gapfill material 306 disposed over backsides of the first DRAM dies 310c can be continuous/integral with one another.

At block 220, the method 200 can continue by planarizing the gapfill material 306 and forming TSV connections and hybrid bond pads 308. In some cases, the gapfill material 306 can be planarized (to thin back the gapfill material 306 disposed on backsides of the first DRAM dies 310c of the DRAM cubes 336), TSV connections (e.g., damascene structures) can be formed, and/or hybrid bond pads 308, which can also be referred to as backside pads (BSP), can be formed. A pitch of the TSVs 305 and the hybrid bond pads 308 can be less than 3 μm (e.g., less than 1 μm). As shown in FIG. 3B, the hybrid bond pads 308 at the backsides of the first DRAM dies 310c of the DRAM cubes 336 can outnumber the TSVs 305, and the hybrid bond pads 308 can be distributed across the reconstructed wafer (including at locations positioned above the gapfill material 306 and that will ultimately be positioned beneath gapfill material when further DRAM cubes are stacked on the reconstructed wafer). Such a distribution of hybrid bond pads 308 is expected to help maintain uniformity of chemical mechanical polishing. In some cases, a pitch of the hybrid bond pads 308 can be less than 3 μm (e.g., less than 1 μm). Hybrid bond pads 308 not coupled to a TSV 305 and/or positioned above or beneath gapfill material 306 can be dummy pads.

At blocks 222-228, the method 200 continues by largely repeating blocks 202-208. For example, at block 222, the method 200 continues by attaching a fourth DRAM wafer to a tape or temporary carrier. In some cases, the fourth DRAM wafer can be an unthinned DRAM wafer and/or a backside of the fourth DRAM wafer can be attached to a tape (e.g., a dicing tape frame) or a temporary carrier, such as using a removable adhesive. The fourth DRAM wafer can be a wafer of known good die (e.g., DRAM die subjected to probing/testing and verified as properly functional before use at block 222 of the method 200).

At block 224, the method 200 continues by stacking a fifth DRAM wafer on the fourth DRAM wafer. In some cases, the fifth DRAM wafer (e.g., a thinned DRAM wafer) can be stacked onto the frontside of the fourth wafer such that a backside of the fifth wafer is bonded to a frontside of the fourth wafer using a wafer-to-wafer (W2W) front-to-back (F2B) hybrid bond. In some embodiments, the fifth DRAM wafer can be bonded to a sacrificial wafer using W2W F2B fusion bond, which can allow (a) forming TSV connections and bond pads at a backside of the fifth DRAM wafer, (b) stacking of the fifth DRAM wafer onto the fourth wafer, and/or (c) thinning the fifth DRAM wafer to expose TSVs and form TSV connections and hybrid bond pads at a frontside of the fifth DRAM wafer. In some cases, a pitch of the TSVs and hybrid bond pads can be less than 3 μm (e.g., less than 1 μm). The fifth wafer can be a wafer of known good die (e.g., DRAM die subjected to probing/testing and verified as properly functional before use at block 224 of the method 200).

At block 226, the method 200 continues by stacking a sixth DRAM wafer on the fifth DRAM wafer. In some cases, the sixth DRAM wafer (e.g., a thinned DRAM wafer) can be stacked onto the frontside of the fifth wafer such that a backside of the sixth wafer is bonded to a frontside of the fifth wafer using a W2W F2B hybrid bond. In some embodiments, the sixth DRAM wafer can be bonded to a sacrificial wafer using W2W F2B fusion bond, which can allow (a) forming TSV connections and hybrid bond pads at a backside of the sixth DRAM wafer and/or the fifth wafer, (b) stacking of the sixth DRAM wafer onto the fifth wafer, (c) stacking of fifth DRAM wafer onto the sixth DRAM wafer, and/or (d) subsequent thinning of the sixth DRAM wafer and/or the fifth DRAM wafer to expose TSVs and form TSV connections and hybrid bond pads at a frontside of the sixth DRAM wafer and/or the frontside of the fifth DRAM wafer, respectively. In some cases, a pitch of the TSVs and hybrid bond pads can be less than 3 μm (e.g., less than 1 μm). The sixth wafer can be a wafer of known good die (e.g., DRAM die subjected to probing/testing and verified as properly functional before use at block 226 of the method 200).

At block 228, the method 200 continues by dicing the wafer stack to form DRAM cubes. The wafer stack resulting from the stack of fourth through sixth wafers can be diced to realize a plurality of three-dimensional stacks (3DS) of memory dies (referred to herein as DRAM cubes) that can each be three-die high. As discussed above, DRAM cubes formed in accordance with other embodiments of the present technology can include two DRAM dies or more than three DRAM dies arranged in a stack.

At block 230, the method 200 continues by stacking DRAM cubes on the reconstructed wafer of DRAM cubes. Referring to FIGS. 2 and 3C together for the sake of example, singulated DRAM cubes (corresponding to DRAM dies 310d-310f in FIG. 3C) can be inverted such that frontsides of sixth DRAM dies 310d of the DRAM cubes are placed face down on backsides of first DRAM dies 310c within the reconstructed wafer discussed above (e.g., with reference to block 218). The inverted DRAM cubes can be stacked on the backsides of the first DRAM dies 310c such that frontsides of the singulated DRAM cubes are bonded to backsides of the first DRAM dies 310c of the DRAM cubes forming the reconstructed wafer using a first stack-to-wafer-reconstruction (S2WR), front-to-back (F2B) hybrid bond 345a. The inverted DRAM cubes can be known good stacks (KGS) as confirmed via functionality testing (e.g., verified through probing/testing) prior to stacking on the reconstructed wafer of DRAM cubes and application of a gapfill material at block 234 below.

At block 232, the method 200 continues (similar to block 216 above) by exposing TSVs 305 of fourth DRAM dies 310f of the DRAM cubes 336. In some cases, the fourth DRAM dies 310f of the DRAM cubes 336 can be thinned (e.g., after removal of the tape/temporary carrier 341) to expose TSVs 305. The thinning can be performed after stacking the DRAM cubes 336 on the reconstructed wafer (e.g., formed at block 218 above) but before filling gaps with gapfill material 306 per block 234 below. Alternatively, the thinning can be performed before stacking the DRAM cubes 336 on the reconstructed wafer, such as before filling gaps with gapfill material 306 per block 234 below. Alternatively, the thinning can be performed after stacking the DRAM cubes 336 on the reconstructed wafer, such as after filling gaps with gapfill material 306 per block 234 below.

At block 234, the method 200 continues by filling in gaps between the DRAM cubes with gapfill material 306 to form a reconstructed wafer. Any suitable gapfill material 306 can be used, such as silicon oxide or silicon monoxide. The gapfill material 306 can fill gaps between the DRAM cubes 336 and/or over backsides of the fourth DRAM dies 310f (corresponding to tops of the DRAM cubes 336). In some embodiments, portions of the gapfill material 306 disposed laterally adjacent the DRAM cubes 336 (e.g., within gaps between adjacent DRAM cubes 336) and portions of the gapfill material 306 disposed over backsides of the fourth DRAM dies 310f can be continuous/integral with one another.

At block 236, the method 200 continues by planarizing the gapfill material 306 and forming TSV connections and hybrid bond pads 308. In some cases, the gapfill material 306 can be planarized (to thin back the gapfill material 306 disposed on backsides of the fourth DRAM dies 310f of the DRAM cubes 336), TSV connections (e.g., damascene structures) can be formed, and hybrid bond pads 308, which can also be referred to as backside pads, can be formed. A pitch of the TSVs 305 and the hybrid bond pads 308 can be less than 3 μm (e.g., less than 1 μm). Similar to the discussion of block 220 above, the hybrid bond pads 308 at the backsides of the fourth DRAM dies 310f of the DRAM cubes 336 can outnumber the TSVs 305, and the hybrid bond pads 308 can be distributed across the most recently reconstructed wafer (including at locations positioned above the gapfill material 306 and that will ultimately be positioned beneath gapfill material when further DRAM cubes are stacked on the most recently reconstructed wafer). Such a distribution of hybrid bond pads 308 is expected to help maintain uniformity of chemical mechanical polishing. In some cases, a pitch of the hybrid bond pads 308 can be less than 3 μm (e.g., less than 1 μm). Hybrid bond pads 308 not coupled to a TSV 305 and/or positioned above or beneath gapfill material 306 can be dummy pads.

In some cases, blocks 222-236 can be repeated a desired number of times. For example, in some embodiments, blocks 222-236 can be repeated six times to realize 24-high stacks of DRAM dies. For the top DRAM dies the final DRAM cubes 336 added to the tops of the (e.g., 24-high) memory stacks 300, the planarization step (block 236) can be skipped. For example, the topmost die 310x (labeled top DRAM in FIG. 3C) of each memory stack 300 can be left unthinned in some embodiments. As a specific example, the topmost die 310x can be a DRAM die made using a different process than the other DRAM dies 310a-310w of the memory stack 300, such as a different process in which TSVs 305 are not formed at a backside of the top DRAM die 310x (e.g., to save costs).

At block 238, the method 200 continues by attaching a dummy silicon wafer. Referring to FIGS. 2 and 3C together for the sake of example, a dummy silicon wafer 315 or substrate can be attached to a backside of the top DRAM die 310x using a W2W fusion bond 348.

At block 240, the method 200 continues by removing the sacrificial or temporary carrier (e.g., the sacrificial or temporary carrier 342 of FIG. 3B) from the interface logic wafer 320.

At block 242, the method 200 continues by forming package-level connections on the interface logic wafer. Referring to FIG. 3C for the sake of example, package level connections can include package-level bond pads 328 (e.g., pads, balls, or pillars formed of copper or another suitable conductive material) and/or pads 325 or plating layers (e.g., pads or plating layers formed of aluminum or another suitable conductive material) formed at frontsides of interface logic dies of the IF logic wafer 320. A pitch of the package-level bond pads 328 can be less than or equal to 10 μm. In some embodiments, the pads 325 can be used for testing the memory stacks 300 to identify known good stacks for incorporation into larger packages and/or memory systems per block 246 below.

At block 244, the method 200 continues by singulating the memory stacks 300, such as using a dicing operation.

At block 246, the method 200 continues by incorporating memory stacks into larger packages and/or memory systems. Referring to FIG. 3D for the sake of example, a memory stack 300 and a logic die 350 (e.g., GPU, TCU, AI accelerator, host device, etc.) can be stacked on a first side 386 of a system substrate 385. In some embodiments, the memory stack 300 and/or the logic die 350 can be stacked onto the system substrate using stack-on-substrate (SoS), front-to-front (F2F), thermo-compression bonding (TCB). The memory stack 300 and the logic die 350 can be communicatively coupled to one another via one or more interconnects 383 formed in a metallization layer dielectric 333 positioned between (a) the memory stack 300 and/or the logic die 350 and (b) the system substrate 385. The memory stack 300 and/or the logic die 350 can be coupled to interconnects and/or TSVs 389a, 389b, respectively, in the system substrate 385 via interconnects 382 (e.g., metal layers, traces, vias) formed in the metallization layer dielectric 333. The memory stack 300 and/or the logic die 350 can be coupled to a plating layer 384 formed at or along a top surface of the metallization layer dielectric 333. The plating layer 384 can facilitate supplying power to the package or system 390, such as for testing the connection between the logic die 350 and the memory stack 300 using the interconnect(s) 383 formed in the metallization layer dielectric 333. The plating layer 384 can additionally, or alternatively, facilitate external connections to external components and/or external systems. An underfill material 329 can be used to fill in gaps between (a) the memory stack 300 and/or the logic die 350 and (b) the metallization layer dielectric 333 (e.g., to protect and/or isolate electrical connections formed using package-level bond pads 328, 358).

Although not shown in FIG. 3D, the method 200 can include encapsulating the memory stack 300 and/or the logic die 350 (e.g., using a molding compound, such as using a molding compound similar to the molding compound 181 of FIG. 1). Additionally, or alternatively, the method 200 can include forming the memory system 390 at a wafer level such that several such memory systems are formed adjacent one another. In such embodiments the method 200 can include singulating the memory systems 190, such as using a dicing operation. Resulting systems 390 can be generally similar to the memory system 190 of FIG. 1.

In some embodiments, the method 200 can include additional/optional steps. For example, the method 200 can include thinning the system substrate 385 to expose the TSVs 389a and/or 389b at a backside 387 of the system substrate 385. In some cases, edge trimming of the system substrate 385 can be performed before thinning (e.g., to avoid chipping of the system substrate 385 while thinning the system substrate 385). The method 200 can additionally, or alternatively, include forming another metallization layer dielectric (e.g., similar to the metallization layer dielectric 333) on the backside 387 of the system substrate 385; stacking another memory stack 300 and/or another logic die 350 on the backside 387 of the system substrate 385; encapsulating (e.g., using a molding compound, such as using a molding compound similar to the molding compound 181 of FIG. 1) the additional memory stack 300 and/or the additional logic die 350; and/or performing a dicing operation to singulate memory systems having memory stacks and/or logic dies on both sides of the system substrate 385.

Although the blocks 202-246 of the method 200 are discussed and illustrated in a particular order, the method 200 of FIG. 2 is not so limited. In other embodiments, all or a subset of one or more of the blocks 202-246 of the method 200 can be performed in a different order. In these and other embodiments, all or a subset of any of the blocks 202-246 of the method 200 can be performed before, during, and/or after all or a subset of any of the other blocks 202-246 of the method 200. Furthermore, a person skilled in the art will readily recognize that the method 200 can be altered and still remain within these and other embodiments of the present technology. For example, all or a subset of one or more blocks 202-246 of the method 200 can be omitted and/or repeated in some embodiments.

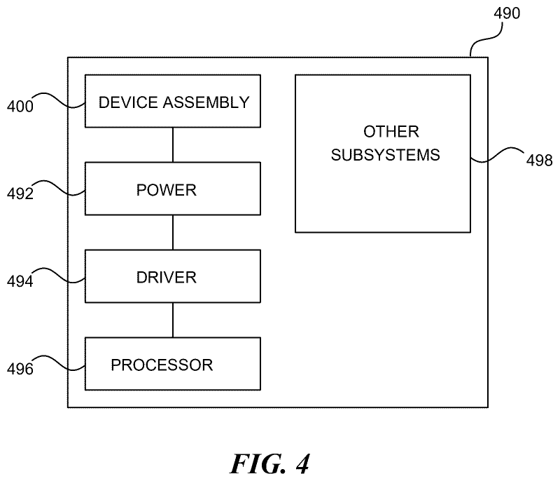

Any one of the semiconductor devices and semiconductor device assemblies described above with reference to FIGS. 1-3D can be incorporated into any of a myriad of larger and/or more complex systems, a representative example of which is system 490 shown schematically in FIG. 4. The system 490 can include a semiconductor device assembly 400 (e.g., a memory stack and/or a memory system, such as similar to the memory stack 100, 300 and/or the memory system 190, 390 described above with reference to FIGS. 1-3D), a power source 492, a driver 494, a processor 496, and/or other subsystems or components 498. The semiconductor device assembly 400 can include features generally similar to those of the semiconductor devices described above with reference to FIGS. 1-3D. The resulting system 490 can perform any of a wide variety of functions, such as memory storage, data processing, and/or other suitable functions. Accordingly, representative systems 490 can include, without limitation, hand-held devices (e.g., mobile phones, tablets, digital readers, and digital audio players), computers, vehicles, appliances and other products. Components of the system 490 may be housed in a single unit or distributed over multiple, interconnected units (e.g., through a communications network). The components of the system 490 can also include remote devices and any of a wide variety of computer readable media.

### C. EXAMPLES

Several aspects of the present disclosure are set forth in the following examples. Any one or more aspects of any two or more of the following examples can be combined with one another, resulting in additional examples that fall within the scope of the present disclosure. Furthermore, one or more elements of any one or more of the following examples can be omitted, replaced, modified, or supplemented while remaining within the scope of the present disclosure. As a specific example, one or more elements of any one or more of the following examples can be replaced, modified, supplemented, or combined with additional aspects of the present disclosure described above and/or with any one or more aspects of any one or more of the following examples. Moreover, although several aspects of the present disclosure are set forth in examples directed to a specific category (e.g., an apparatus, a system, a method, a computer-readable media, etc.), these aspects of the present disclosure can be set forth in examples directed to any other category without departing from the scope of the present disclosure.
1. A memory stack, comprising:
an interface (IF) logic die;
a plurality of memory cubes arranged in a vertical stack on the IF logic die, wherein each memory cube of the plurality of memory cubes includes a plurality of memory dies; and
gapfill material disposed over the IF logic die and laterally adjacent each of the memory cubes.
2. The memory stack of example 1, wherein the gapfill material is further disposed over a topmost die of each memory cube of the plurality of memory cubes such that the gapfill material is positioned between immediately adjacent memory cubes of the plurality of memory cubes in the vertical stack.
3. The memory stack of example 2, wherein the gapfill material disposed over the topmost die of each memory cube and the gapfill material disposed laterally adjacent each memory cube together form a continuous structure.
4. The memory stack of any of examples 1-3, further comprising dummy pads disposed at an interface between the gapfill material and the IF logic die.
5. The memory stack of any of examples 1-4, wherein each memory die of the plurality of memory dies of each memory cube of the plurality of memory cubes includes through-silicon vias (TSVs) arranged with a pitch of less than or equal to 3 micrometers.
6. The memory stack of example 5, wherein the TSVs are arranged with a pitch of less than or equal to 1 micrometer.
7. The memory stack of any of examples 1-6, wherein each memory die of the plurality of memory dies of each memory cube of the plurality of memory cubes includes hybrid bond pads formed at top and bottom sides that are arranged with a pitch of less than or equal to 3 micrometers.
8. The memory stack of example 7, wherein the hybrid bond pads are arranged with a pitch of less than or equal to 1 micrometer.
9. The memory stack of any of examples 1-8, wherein immediately adjacent memory dies of the plurality of memory dies of each memory cube are bonded to one another via hybrid bonds.
10. The memory stack of any of examples 1-9, wherein immediately adjacent memory cubes of the plurality of memory cubes in the vertical stack are bonded to one another via hybrid bonds.
11. The memory stack of any of examples 1-10, further comprising dummy pads positioned within the gapfill material disposed laterally adjacent each of the memory cubes.
12. The memory stack of any of examples 1-11, wherein a bottommost memory die of the plurality of memory dies of a bottommost memory cube of the plurality of memory cubes in the vertical stack is bonded to the IF logic die via a hybrid bond.
13. The memory stack of any of examples 1-12, further comprising package-level connections formed at a side of the IF logic die opposite the plurality of memory cubes.
14. The memory stack of example 13, wherein the package-level connections are disposed at a pitch of less than or equal to 10 micrometers.
15. The memory stack of any of examples 1-14, further comprising one or more test pads disposed at a side of the IF logic die opposite the plurality of memory cubes.
16. The memory stack of any of examples 1-15, further comprising a dummy silicon substrate bonded to a topmost memory die of the vertical stack via a fusion bond.
17. The memory stack of any of examples 1-16, wherein each memory cube of the plurality of memory cubes comprises three memory dies.
18. A memory system, comprising:
a system substrate having a first side and a second side opposite the first side;
a logic die; and
a memory stack including:
   an interface (IF) logic die,
   a plurality of memory cubes arranged in a vertical stack on the IF logic die, wherein each memory cube of the plurality of memory cubes includes a plurality of memory dies, and
   gapfill material disposed over the IF logic die and laterally adjacent each of the memory cubes.
19. The memory system of example 18, wherein the logic die and the memory stack are both disposed on the first side of the system substrate and communicatively coupled to one another via one or more interconnects formed in a metallization layer dielectric disposed at the first side of the system substrate.
20. The memory system of example 19, further comprising a plating layer disposed in or on the metallization layer dielectric and usable to (a) supply power to the logic die and/or the memory stack, (b) transmit communications between (i) the logic die and/or the memory stack and (ii) a component external to the memory system, or (c) a combination thereof.
21. The memory system of example 20, wherein the memory stack further comprises package-level connections disposed at a pitch of less than or equal to 10 micrometers at an interface between the IF logic die and the metallization layer dielectric.
22. A method, comprising:
stacking a first set of DRAM cubes on an interface (IF) logic wafer using first stack-to-wafer hybrid bonds;
filling in gaps between the DRAM cubes using a gapfill material to form a reconstructed wafer; and

stacking a second set of DRAM cubes on the reconstructed wafer such that the first and second DRAM cubes are arranged in a plurality of vertical stacks and are bonded to one another using second stack-to-wafer hybrid bonds.
23. The method of example 22, wherein filling in the gaps includes disposing the gapfill material over topmost surfaces of the first set of DRAM cubes such that the gapfill material forms a continuous structure that encapsulates the first set of DRAM cubes.
24. The method of example 23, further comprising planarizing a top surface of the gapfill material and forming hybrid bond pads at the top surface with a pitch of less than or equal to micrometers.
25. The method of any of examples 22-24, wherein filling in the gaps includes disposing the gapfill material over bond pads at locations laterally offset from an interface between the IF logic wafer and the first set of DRAM cubes.
26. The method of any of examples 22-25, further comprising forming package-level connections at a side of the IF logic wafer opposite the first and second sets of DRAM cubes, and with a pitch of less than or equal to 10 micrometers.
27. The method of any of examples 22-26, further comprising:
singulating a memory stack from the IF wafer, the reconstructed wafer, and the second set of DRAM cubes, wherein the memory stack includes an IF logic die from the IF wafer, a first DRAM cube from the reconstructed wafer, and a second DRAM cube from the second set of DRAM cubes; and
attaching the IF logic die to a system substrate using thermo-compression bonding.
28. The method of example 27, wherein attaching the IF logic die to the system substrate includes bonding package-level connections to corresponding bond pads disposed at a first side of the system substrate.
29. The method of example 27 or example 28, further comprising coupling the memory stack to a logic die via one or more interconnects formed in a metallization layer dielectric disposed at a first side of the system substrate.
30. The method of any of examples 22-29, wherein forming the first set of DRAM cubes includes:
forming a stack of a plurality of DRAM wafers using wafer-to-wafer hybrid bonds; and
dicing the stack of the plurality of DRAM wafers into individual DRAM cubes.

### D. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A memory stack, comprising:
an interface (IF) logic die;
a plurality of memory cubes arranged in a vertical stack on the IF logic die, wherein each memory cube of the plurality of memory cubes includes a plurality of memory dies; and
gapfill material disposed over the IF logic die and laterally adjacent each of the memory cubes.

2. The memory stack of claim 1, wherein the gapfill material is further disposed over a topmost die of each memory cube of the plurality of memory cubes such that the gapfill material is positioned between immediately adjacent memory cubes of the plurality of memory cubes in the vertical stack.

3. The memory stack of claim 2, wherein the gapfill material disposed over the topmost die of each memory cube and the gapfill material disposed laterally adjacent each memory cube together form a continuous structure.

4. The memory stack of claim 1, further comprising dummy pads disposed at an interface between the gapfill material and the IF logic die.

5. The memory stack of claim 1, wherein each memory die of the plurality of memory dies of each memory cube of the plurality of memory cubes includes through-silicon vias (TSVs) arranged with a pitch of less than or equal to 3 micrometers.

6. The memory stack of claim 5, wherein the TSVs are arranged with a pitch of less than or equal to 1 micrometer.

7. The memory stack of claim 1, wherein each memory die of the plurality of memory dies of each memory cube of the plurality of memory cubes includes hybrid bond pads formed at top and bottom sides that are arranged with a pitch of less than or equal to 3 micrometers.

8. The memory stack of claim 7, wherein the hybrid bond pads are arranged with a pitch of less than or equal to 1 micrometer.

9. The memory stack of claim 1, wherein immediately adjacent memory dies of the plurality of memory dies of each memory cube are bonded to one another via hybrid bonds.

10. The memory stack of claim 1, wherein immediately adjacent memory cubes of the plurality of memory cubes in the vertical stack are bonded to one another via hybrid bonds.

11. The memory stack of claim 1, further comprising dummy pads positioned within the gapfill material disposed laterally adjacent each of the memory cubes.

12. The memory stack of claim 1, wherein a bottommost memory die of the plurality of memory dies of a bottommost memory cube of the plurality of memory cubes in the vertical stack is bonded to the IF logic die via a hybrid bond.

13. The memory stack of claim 1, further comprising package-level connections formed at a side of the IF logic die opposite the plurality of memory cubes.

14. The memory stack of claim 13, wherein the package-level connections are disposed at a pitch of less than or equal to 10 micrometers.

15. The memory stack of claim 1, further comprising one or more test pads disposed at a side of the IF logic die opposite the plurality of memory cubes.

16. The memory stack of claim 1, further comprising a dummy silicon substrate bonded to a topmost memory die of the vertical stack via a fusion bond.

17. The memory stack of claim 1, wherein each memory cube of the plurality of memory cubes comprises three memory dies.

18. A memory system, comprising:
a system substrate having a first side and a second side opposite the first side;
a logic die; and
a memory stack including:
an interface (IF) logic die,
a plurality of memory cubes arranged in a vertical stack on the IF logic die, wherein each memory cube of the plurality of memory cubes includes a plurality of memory dies, and
gapfill material disposed over the IF logic die and laterally adjacent each of the memory cubes.

19. The memory system of claim 18, wherein the logic die and the memory stack are both disposed on the first side of the system substrate and communicatively coupled to one another via one or more interconnects formed in a metallization layer dielectric disposed at the first side of the system substrate.

20. The memory system of claim 19, further comprising a plating layer disposed in or on the metallization layer dielectric and usable to (a) supply power to the logic die and/or the memory stack, (b) transmit communications between (i) the logic die and/or the memory stack and (ii) a component external to the memory system, or (c) a combination thereof.

21. The memory system of claim 20, wherein the memory stack further comprises package-level connections disposed at a pitch of less than or equal to 10 micrometers at an interface between the IF logic die and the metallization layer dielectric.
